(19) United States
(12) Patent Application Publication
(10) Pub. No.: US 2006/0261436 A1
(43) Pub. Date: Nov. 23, 2006

(54) Electronic device including a trench field isolation region and a process for forming the same

(75) Inventors: Michael D. Turner, San Antonio, TX (US); John J. Hackenberg, Austin, TX (US); Toni D. Van Gompel, Austin, TX (US)

Correspondence Address: LARSON NEWMAN ABEL POLANSKY & WHITE, LLP, 5914 WEST COURTYARD DRIVE, SUITE 200, AUSTIN, TX, 78730, US

(73) Assignee: Freescale Semiconductor, Inc., Austin, TX (US)

(21) Appl. No.: 11/132,936

(22) Filed: May 19, 2005

(51) Int. Cl. H01L 29/00; H01L 21/76

(52) U.S. Cl. 257/506; 438/424; 438/435; 257/510

(57) ABSTRACT

A process can be used to achieve the benefits of corner rounding of a semiconductor layer near an edge of a trench field isolation region without having the bird's beak or stress issues that occur with a conventional SOI device. A trench can be partially etched into a semiconductor layer, and a liner layer may be formed to help round corners of the second semiconductor layer. In one embodiment, the trench can be etched deeper and potentially expose an underlying buried oxide layer. Formation of the trench field isolation region can be completed, and electronic components can be formed within the semiconductor layer. An electronic device, such as an integrated circuit, will have a liner layer that extends only partly, but not completely, along a sidewall of the trench. In another embodiment, the process can be extended to other substrates and is not limited only to SOI substrates.

### BACKGROUND

1. Field of the Disclosure

The present disclosure relates to electronic devices and processes for forming them, and more particularly to electronic devices including trench field isolation regions and processes for forming the same.

2. Description of the Related Art

As device performance becomes more and more demanding, semiconductor devices are now formed using semiconductor-on-insulator (“SOI”) substrates. In order to achieve a reasonably high component density, trench field isolation regions are typically formed between semiconductor devices. Typically, a trench liner is typically formed to help round the top corners of a semiconductor layer to improve gate dielectric integrity.

FIG. 1 includes an illustration of a cross-sectional view of a portion of an electronic device. The electronic device includes a substrate 12, an insulating layer 14, which can be a buried oxide, and a semiconductor layer 162 that overlies the insulating layer 14. The semiconductor layer 162 is patterned to form openings (not illustrated) that extend through the semiconductor layer 162 to the insulating layer 14. A thermal oxidation is typically performed and grows a liner layer 164. During the formation of the liner layer 164, top corners 166 of the semiconductor layer 162 are rounded in order to improve gate dielectric integrity. However, the thermal oxidation also causes corner rounding near the bottom of the semiconductor layer 162, as seen with rounded corners 168. The rounded corners 168 within the semiconductor layer 162 near the insulating layer 14 are undesired. An insulating layer 18 can then be formed within the openings, with portions of the insulating layer 18 overlying the semiconductor layer 162 being removed using a conventional process. During subsequent thermal cycles unacceptable levels of stress may be exerted by the trench field isolation regions (combination of liner layers 164 and insulating layers 18) onto the semiconductor layer 162. The stress may cause electrical characteristics of the devices to change, defects, faults, fractures to form within the semiconductor layer 162, or, in extreme cases, delamination of the semiconductor layer 162 from the insulating layer 14.

Therefore, the industry has had two alternatives when using trench field isolation regions with SOI substrates: form the liner layer 164 and deal with the stress issues or do not form the liner layer 164 and thicken the gate dielectric layer to achieve at least a minimally acceptable gate dielectric integrity near the edges of trench field isolation regions. The two alternatives are unacceptable for robust, high performance electronic devices.

### BRIEF DESCRIPTION OF THE DRAWINGS

Embodiments are illustrated by way of example and are not limited in the accompanying figures.

FIG. 1 includes an illustration of a cross-sectional view of a portion of an electronic device that includes an SOI substrate, wherein the semiconductor layer has rounded corners. (Prior Art)

FIG. 2 includes an illustration of a cross-sectional view of a portion of an electronic device workpiece after forming a mask.

FIG. 3 includes an illustration of a cross-sectional view of the workpiece of FIG. 2 after forming a trench extending partly, but not completely, through a semiconductor layer.

FIG. 4 includes an illustration of a cross-sectional view of the workpiece of FIG. 3 after rounding corners of the semiconductor layer near the top of the trench.

FIG. 5 includes an illustration of a cross-sectional view of the workpiece of FIG. 4 after extending the trench through the rest of the semiconductor layer to expose an underlying insulating layer.

FIG. 6 includes an illustration of a cross-sectional view of the workpiece of FIG. 5 after forming an insulating layer that fills the trench.

FIG. 7 includes an illustration of a cross-sectional view of the workpiece of FIG. 6 after formation of a trench field isolation region is substantially completed.

FIG. 8 includes an illustration of a cross-sectional view of the workpiece of FIG. 7 after removing remaining portions of layers overlying the semiconductor layer.

FIG. 9 includes an illustration of a cross-sectional view of the workpiece of FIG. 8 after forming electronic components.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments.

### DETAILED DESCRIPTION

A process can be used to achieve the benefits of corner rounding of a semiconductor layer near an edge of a trench field isolation region without having the bird's beak or stress issues that occur with a conventional SOI device. A trench can be partially etched into a semiconductor layer, and a liner layer may be formed to help round corners of the second semiconductor layer. After forming the liner layer, the trench can be etched deeper and potentially expose an underlying buried oxide layer in one embodiment. Formation of the trench field isolation region can be completed, and electronic components can be formed within the semiconductor layer. An electronic device, such as an integrated circuit, will have a liner layer that extends only partly, but not completely, along a sidewall of the trench. The formation of the liner layer before completely etching the trench can significantly reduce or eliminate the bird's beak and stress issues that occur in conventional devices. In another embodiment, the process can be extended to other substrates and is not limited only to SOI substrates.

In a first aspect, a process for forming an electronic device can include etching a trench to a first depth in the semiconductor material and forming a first insulating layer along a sidewall of the trench. The process can also include etching the trench to a second depth in the semiconductor material that is deeper than the first trench, wherein etching the trench to the second depth is performed after forming the first insulating layer along the sidewall of the trench, forming a second insulating layer over the semiconductor material and within the trench to fill the opening, and removing a portion of the second insulating layer lying outside the trench to define a trench field isolation region.

In one embodiment of the first aspect, the process further includes forming a pad layer over the semiconductor material and forming an oxidation-resistant layer over the pad layer before forming a mask. In a particular embodiment, the process further includes patterning the oxidation-resistant layer to define an opening and patterning the pad layer before etching the trench to the first depth, wherein the opening extends through the pad layer after patterning the pad layer. In another embodiment, the semiconductor material is part of a semiconductor layer that overlies a buried oxide layer that overlies a substrate. In still another embodiment, the semiconductor material is part of a substantially monocrystalline semiconductor substrate. In yet another embodiment, forming the first insulating layer along the sidewall of the trench includes forming an oxide film along the sidewall and a bottom of the trench and etching the oxide film to expose the bottom of the trench. In a particular embodiment, forming the first insulating layer along the sidewall of the trench includes forming a nitride film over the oxide film and etching the nitride film to expose a portion of the oxide film lying along the bottom of the trench.

In a further embodiment of the first aspect, forming the first insulating layer includes forming the first insulating layer to a thickness in a range of approximately 1 to approximately 30 nm as measured along the bottom of the trench. In still a further embodiment, removing the portions of the second insulating layer is performed using chemical-mechanical polishing. In yet a further embodiment, removing the portions of the second insulating layer is performed by etching the second insulating layer.

In another embodiment of the first aspect, the process further includes forming a transistor, wherein at least a portion of the transistor is formed within the semiconductor material adjacent to the trench field isolation region. In a particular embodiment, forming the transistor includes forming a gate dielectric layer from or over the semiconductor material, forming a gate electrode over the gate dielectric layer, and forming spaced-apart source/drain regions within the semiconductor material, wherein a channel region lies between the spaced-apart source/drain regions and under the gate electrode.

In a second aspect, an electronic device can include a semiconductor material that defines a trench including a sidewall and a bottom and a trench field isolation region adjacent to the semiconductor material at the sidewall. The trench field isolation region can include a first insulating layer extending from a first point near a top of the sidewall of the trench to a second point that lies at a first depth, wherein the second point is spaced apart from the bottom of the trench. The trench field isolation region can also include a second insulating layer that fills the trench and extends to a third point that lies at a second depth that is closer to the bottom of the trench compared to the second point.

In one embodiment of the second aspect, the semiconductor material is part of a semiconductor layer that overlies a buried oxide layer that overlies a substrate. In another embodiment, the semiconductor material is part of a substantially monocrystalline semiconductor substrate. In still another embodiment, the first insulating layer includes an oxide film. In a particular embodiment, the first insulating layer further includes a nitride film, wherein the nitride film lies between the oxide film and the second insulating layer.

In a further embodiment of the second aspect, the electronic device further includes a transistor, wherein at least a portion of the transistor lies within the semiconductor material and adjacent to the trench field isolation region. In still a further embodiment, the transistor includes a gate dielectric layer overlying the semiconductor material, a gate electrode overlying the gate dielectric layer, and spaced-apart source/drain regions and a channel region within the semiconductor material, wherein the channel region lies between the spaced-apart source/drain regions and under the gate electrode.

In a third aspect, a process for forming an electronic device can include forming a first oxide layer over a semiconductor layer that overlies a buried oxide layer that overlies a substrate, forming a nitride layer over the oxide layer, and forming an opening that extends through the nitride layer and the oxide layer, and a trench extending to a first depth into the semiconductor layer, wherein the trench includes a sidewall and a bottom. The process can also include forming a second oxide layer along the sidewall and bottom of the trench, etching a first portion of the second oxide layer to expose the semiconductor layer lying along the bottom of the trench, wherein a second portion of the second oxide layer lies along a sidewall of the trench after etching the first portion is substantially completed, and etching the semiconductor layer to extend the trench through the semiconductor layer and expose the buried oxide layer. The process can further include forming a third oxide layer to fill the trench. A first portion of the third oxide layer extends into the trench to a location deeper than the first depth, and a second portion of the third oxide layer overlies the nitride layer and the first oxide layer. The process can still further include removing the second portion of the third oxide layer, removing remaining portions of the nitride layer and the first oxide layer, and forming an electronic component, wherein at least a portion of the electronic component lies within the semiconductor layer.

Before addressing details of embodiments described below, some terms are defined or clarified. Group numbers corresponding to columns within the Periodic Table of the elements use the “New Notation” convention as seen in the CRC Handbook of Chemistry and Physics, 81^{st} Edition (2000).

The term “substrate” is intended to mean a base material. An example of a substrate includes a quartz plate, a monocrystalline semiconductor wafer, a semiconductor-on-insulator wafer, etc. The reference point for a substrate is the beginning point of a process sequence.

The term “workpiece” is intended to mean a substrate and, if any, one or more layers one or more structures, or any combination thereof attached to the substrate, at any particular point of a process sequence. Note that the substrate may not significantly change during a process sequence, whereas the workpiece significantly changes during the process sequence. For example, at the beginning of a process sequence, the substrate and workpiece are the same. After a layer is formed over the substrate, the substrate has not changed, but now the workpiece includes the combination of the substrate and the layer.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Additionally, for clarity purposes and to give a general sense of the scope of the embodiments described herein, the use of the terms “a” or “an” are employed to describe one or more articles to which “a” or “an” refers. Therefore, the description should be read to include one or at least one whenever “a” or “an” is used, and the singular also includes the plural unless it is clear that the contrary is meant otherwise.

Unless otherwise defined, all technical and scientific terms used herein have the same meaning as commonly understood by one of ordinary skill in the art to which this invention belongs. All publications, patent applications, patents, and other references mentioned herein are incorporated by reference in their entirety. In case of conflict, the present specification, including definitions, will control. In addition, the materials, methods, and examples are illustrative only and not intended to be limiting.

Other features and advantages of the invention will be apparent from the following detailed description, and from the claims.

To the extent not described herein, many details regarding specific materials, processing acts, and circuits are conventional and may be found in textbooks and other sources within the semiconductor and microelectronic arts.

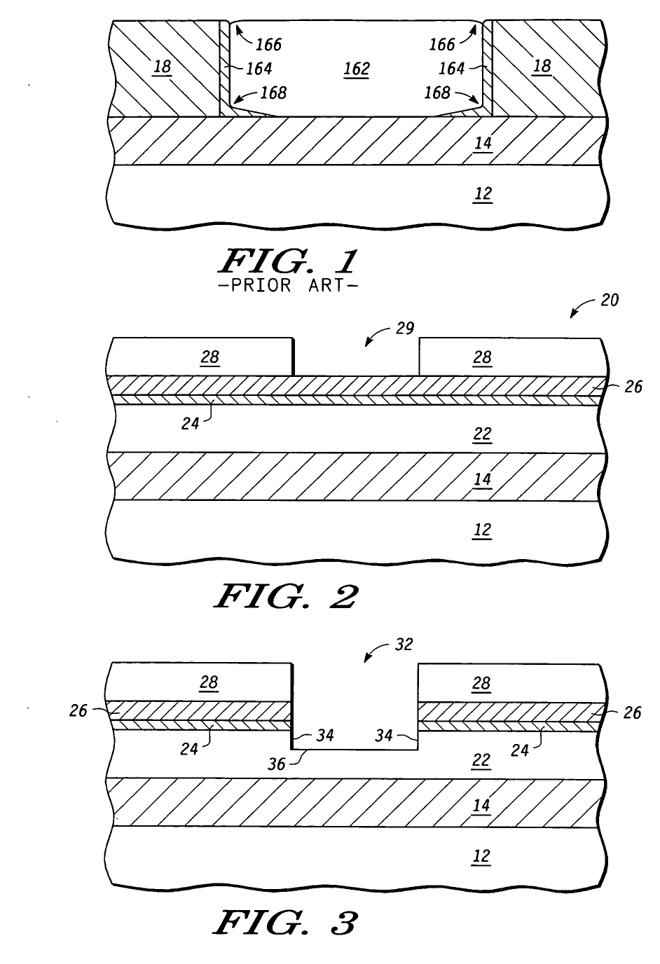

FIG. 2 includes an illustration of a cross-sectional view of an electronic device workpiece 20, which includes a substrate 12, an insulating layer 14, and a semiconductor layer 22. The substrate 12 can include an electronic device substrate, such as a flat panel substrate, a semiconductor device substrate, or the other conventional substrate used for forming electronic devices. In one embodiment, the substrate 12 is a substantially monocrystalline semiconductor material, such as one or more Group 14 elements (e.g., C, Si, Ge), a III-V semiconductor, a II-VI semiconductor, or other appropriate material. Clearly, the substrate 12 could include one or more other materials that can be used in place of or in conjunction with silicon. The insulating layer 14 overlies the substrate 12. The insulating layer 14 includes an oxide, nitride, or a combination thereof. The insulating layer 14 (usually referred to as a buried oxide layer or a BOX layer) has a thickness sufficient to substantially reduce parasitic capacitance between the substrate 12 and subsequently formed electronic devices within the semiconductor layer 22. In one embodiment, the insulating layer 14 has a thickness of at least 100 nm. The semiconductor layer 22 can include one or more Group 14 elements (e.g., C, Si, Ge), a III-V semiconductor, a II-VI semiconductor, or other appropriate material, and in one embodiment, the semiconductor layer 22 is a substantially monocrystalline silicon layer. The thickness of the semiconductor layer 22 is in a range of approximately 10 to approximately 200 nm. The combination of the substrate 12, insulating layer 14, and semiconductor layer 22 may be obtained from one or more commercially available sources or the layers 14 and 22 can be formed from or over the substrate 12 using one or more conventional techniques.

A pad layer 24 and an oxidation-resistant layer 26 are formed over the semiconductor layer 22, as illustrated in FIG. 2. In one embodiment, the pad layer 24 includes an oxide (e.g., silicon dioxide) that is thermally grown from or deposited over the semiconductor layer 22, and the oxidation-resistant layer 26 includes a nitride (e.g., silicon nitride) that is deposited over the pad layer 24. In one non-limiting embodiment, the pad layer 24 can have a thickness in a range of approximately 2 to approximately 40 nm, and the oxidation-resistant layer 26 can have a thickness in a range of approximately 10 to approximately 200 nm.

A mask 28 is formed over pad layer 24 and the oxidation-resistant layer 26 using a conventional lithographic technique to define an opening 29. In one embodiment, the mask 28 includes a resist material, such as deep ultraviolet resist.

As illustrated in FIG. 3, the oxidation-resistant layer 26 and the pad layer 24 are patterned to form openings that extend through those layers, and a trench 32 is formed that extends to a first depth within the semiconductor layer 22. The trench 32 extends partly, but not completely, through the semiconductor layer 22. The trench 32 includes one or more sidewalls 34 and extends to a bottom 36 that lies substantially at the first depth. In one embodiment, the openings in the oxidation-resistant layer 26 and the pad layer 24 and the sidewalls 34 of the trench 32 are substantially coterminous with one another. The sidewalls 34 can be substantially vertical or may include a slight taper (i.e., slightly off vertical).

In one embodiment, the oxidation-resistant layer 26 includes silicon nitride, the pad layer 24 includes silicon dioxide, and the semiconductor layer 22 includes silicon or silicon germanium. The openings and trench 32 can be formed by dry etching the layers. Different etch chemistries can be used during the etch. The oxidation-resistant layer 26 can be etched using an etch chemistry that is tailored for silicon nitride and has good selectivity to oxide. The pad layer 24 can be etched using an etch chemistry that is tailored for silicon dioxide and has good selectivity to silicon or silicon germanium. The semiconductor layer 22 can be etched using an etch chemistry that tailored to silicon or silicon germanium. The same etch chemistries can be used for combinations of some of the layers. For example, the same etch chemistry may be used for the oxidation-resistant layer 26 and pad layer 24. Such etch chemistry may have good selectivity to silicon or silicon germanium. Alternatively, the same etch chemistry maybe used for the pad layer 24 and the semiconductor layer 22. Still other etch chemistries can be used, particularly if the composition of the oxidation-resistant layer 26, the pad layer 24, the semiconductor layer 22, or any combination thereof would be different from those previously described.

Each of etching of the oxidation-resistant layer 26 and the pad layer 24 may be performed as a timed etch or using endpoint detection with an optional timed overetch. The etching of the semiconductor layer 22, when forming the trench 32, can be performed as a timed etch.

After the trench 32 has been formed, the mask 28 can be removed using a conventional ashing technique. In an alternative embodiment, the mask 28 can be removed after patterning the oxidation-resistant layer 26, after patterning the pad layer 24, or after forming the trench 32. In this embodiment, the oxidation-resistant layer 26 or combination of the oxidation-resistant layer 26 and the pad layer 24 can act as a hard mask while etching the trench 32 into the semiconductor layer 22.

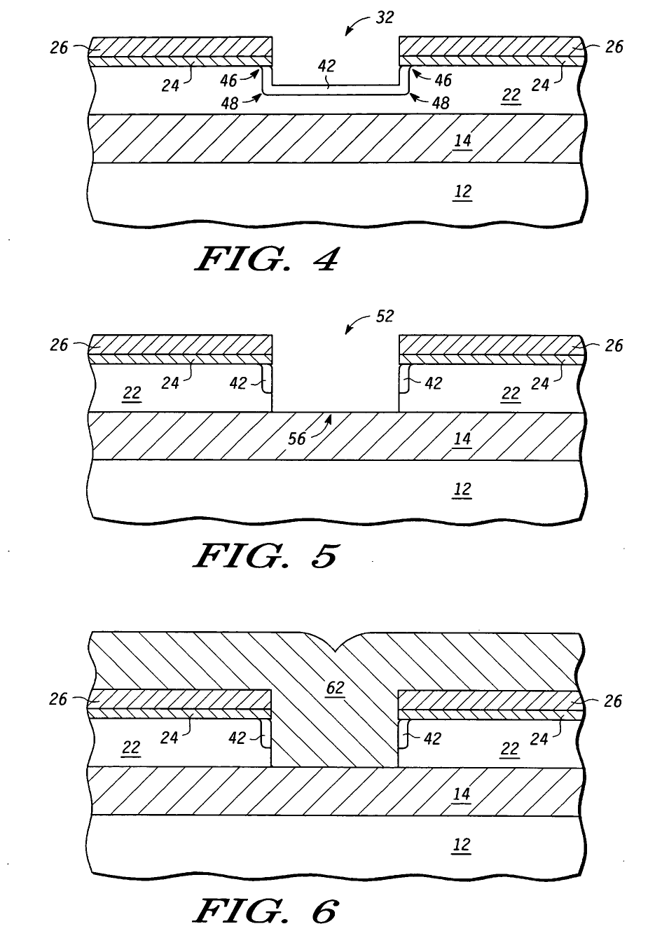

A liner layer 42 can be formed along the exposed surfaces of the semiconductor layer 22, as illustrated in FIG. 4. The liner layer 42 can include one or more insulating films. In one embodiment, the liner layer 42 is formed by thermally oxidizing a portion of the semiconductor layer 22 using an oxygen-containing ambient (e.g., O₂, O₃, N₂O, other suitable oxidizing species, or any combination thereof) to form an oxide layer. The oxidation-resistant layer 26 does not significantly oxidize during the thermal oxidation, and therefore can act as an oxidation mask during thermal oxidation. In one embodiment, the liner layer 42, as measured along the bottom of the trench 32, has a thickness in a range of approximately 1 to approximately 30 nm.

The thermal oxidation can cause corner rounding, which results in rounded corners 46 and 48. The rounded corner 46 lies at or near the top of the sidewall 34 of the trench 32. The rounded corner 46 helps to improve gate dielectric integrity. Unlike the rounded corner 18 in FIG. 1, the rounded corner 48, as illustrated in FIG. 4, lies at the bottom of the trench 32 and is spaced apart from the bottom of the semiconductor layer 22. Thus, although rounded corner 48 is spaced apart from the top of the trench 32, its location does not significantly adversely impact the electronic device being formed.

In an alternative embodiment, the liner layer 42 can include one or more other insulating films that can be used in conjunction with or in place of the thermal oxide film. In one embodiment, a nitride film can be deposited using a conventional technique over the thermal oxide film. The nitride film can have a thickness in a range of approximately 1 to approximately 5 nm and may help to reduce erosion of the oxide film within the liner layer 42 during subsequent oxide etches, for example, when removing the pad layer 24, when forming and removing gate dielectric layers for different parts of the electronic device, etc.

The portion of the liner layer 42 lying along the bottom of the trench 32 is removed, as illustrated in FIG. 5. The portion can be removed by using a conventional anisotropic etching technique to expose the underlying semiconductor layer 22. The semiconductor layer 22 is then etched to remove the remaining portion of the semiconductor layer 22 to expose the insulating layer 14 along the bottom 56 of the trench 52 that extends to a second depth that is deeper than the first depth (of the trench 32). The oxidation-resistant layer 26 can be used a hard mask during the etching of the semiconductor layer 22. Alternatively, another mask (not illustrated) can be formed that has an opening substantially coterminous with the opening in the oxidation-resistant layer 26. The remaining portion of the liner layer 42 extends from a point near the top of the sidewall of the trench 52 to a deeper point within the trench 52 but spaced apart from the bottom 56 of the trench 52. Because the liner layer 42 and corner rounding was performed prior to etching the trench 52 to the second depth, the problems with corner rounding and bird's beak formation along the bottom of the semiconductor layer 22 can be substantially prevented. The etch chemistry used for etching the semiconductor layer 22 for the trench 52 (FIG. 5) can be the same etch chemistry used for etching the semiconductor layer 22 for the trench 32 (FIG. 3). In another embodiment, different etch chemistries could be used.

In another embodiment, the trench 52 may not extend completely through the semiconductor layer 22. In still another embodiment (not illustrated), the combination of the semiconductor layer 22, insulating layer 14, and substrate 12 may be replaced by a monocrystalline semiconductor substrate. In this embodiment, a substantially similar trench 52 and remaining portion of the liner layer 42 can be formed.

An insulating layer 62 is formed to fill the trench 52, as illustrated in FIG. 6. The insulating layer 62 can include one or more films of an oxide, a nitride, or a combination thereof. In one specific embodiment, the insulating layer 62 is formed by depositing an oxide film from tetraethylorthosilicate (TEOS) to a thickness that is at least one half the depth of the trench 52, and typically is at least as deep at the trench 52. The insulating layer 62 may have an undulating upper surface, a substantially flat upper surface, or something in-between.

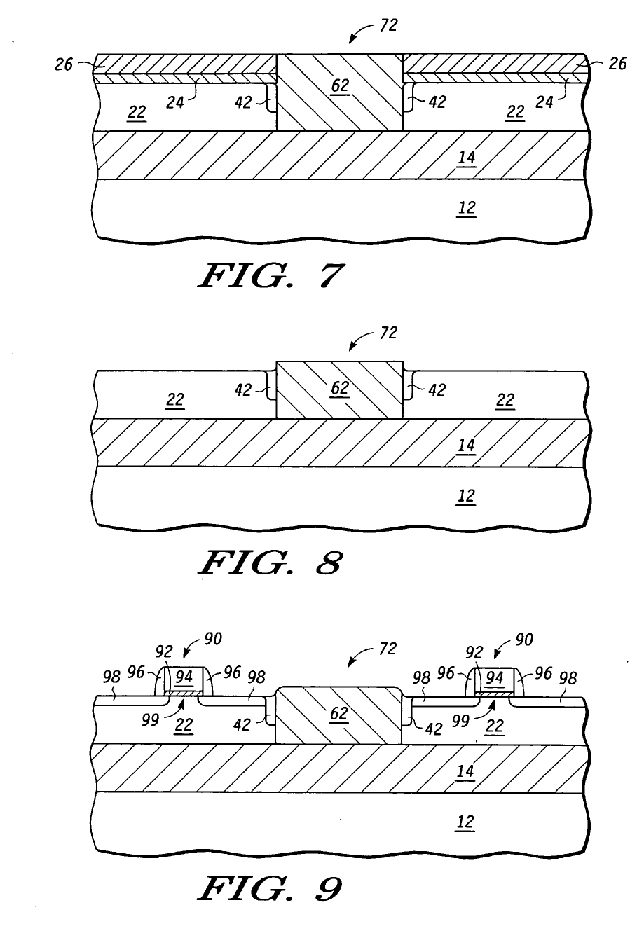

Portions of the insulating layer 62 outside the trench and overlying the oxidation-resistant layer 26 are removed to form a trench field isolation region 72, as illustrated in FIG. 7. The trench field isolation region 72 includes the liner layer 42 and the insulating layer 62. In one embodiment, a chemical-mechanical polishing can be used, wherein the oxidation-resistant layer 26 can also act as a polish-stop layer. In another embodiment, the polishing operation could be continued until another layer underlying the oxidation-resistant layer 26 is reached.

In another embodiment, an etching process can be performed until the oxidation-resistant layer 26 is exposed, wherein the oxidation-resistant layer 26 can also act as an etch-stop layer. The etching may be performed as a timed etch or using endpoint detection (detecting the oxidation-resistant layer 26 has been reached) with a timed overetch. In one particular embodiment when the insulating layer 62 has an undulating surface, as deposited, a conventional resist-etch-back process can be used. As the insulating layer 62 is etched, the etch chemistry may be changed before the oxidation-resistant layer 26 is reached to improve the etch selectivity (e.g., ratio of oxide etch rate to nitride etch rate is increased), and thus, decrease the likelihood of removing substantially all of the oxidation-resistant layer 26.

Remaining portions of the oxidation-resistant layer 26 and pad layer 24 are removed using conventional techniques, as illustrated in FIG. 8, if not previously removed when removing portions of the insulating layer 62 that were outside the trench. A wet etching technique, dry etching technique, or any combination thereof can be used to remove the oxidation-resistant layer 26 or the pad layer 24. In one embodiment, a dilute HF solution can be used to remove the pad layer 24. Relatively small amounts of the liner layer 42 and the insulating layer 62 may be removed if the pad layer 24, the liner layer 42, and the insulating layer 62 comprise substantially the same material (e.g., SiO₂). Such relatively small amounts typically do not significantly adversely affect the electronic device.

At this point in the process, transistors 90, which are electronic components, can be formed, as illustrated in FIG. 9. In one embodiment, the transistors will have their active regions (i.e., source/drain and channel regions) formed within the semiconductor layer 22. The transistors 90 include one or more n-channel transistors, one or more p-channel transistors, or any combination thereof. Other electronic components, including resistors and capacitors, can be formed from portions of the semiconductor layer 22, if desired.

Optionally, one or more well dopants (not illustrated) can be introduced into the semiconductor layer 22. A well dopant can allow for the formation for enhancement-mode transistors, depletion-mode transistors, or a combination thereof. Also, the well dopants can be used, in part, to determine the threshold voltages of the transistors being formed. Additionally, a separate threshold adjust dopant can be used in place of or in conjunction with the well dopant. An optional thermal cycle may be performed to activate the dopant(s). In another embodiment, the dopant(s) may be activated during subsequent processing

A gate dielectric layer 92 is formed over the semiconductor layer 22, as illustrated in FIG. 9. The gate dielectric layer 92 may be thermally grown using an ambient including an oxygen-containing ambient (e.g., O₂, O₃, N₂O, other suitable oxidizing species, or any combination thereof), or may be deposited using a conventional chemical vapor deposition technique, physical vapor deposition technique, atomic layer deposition technique, or a combination thereof. The gate dielectric layer 92 can include one or more films of silicon dioxide, silicon nitride, silicon oxynitride, a high-k material (e.g., dielectric constant (k) greater than 8), or any combination thereof. The high-k material can include HfₐO_{b}N_{c}, HfₐSi_{b}O_{c}, HfₐSi_{b}O_{c}N_{d}, HfₐZr_{b}O_{c}N_{d}, HfₐZr_{b}Si_{c}O_{d}Nₑ, HfₐZr_{b}O_{c}, ZrₐSi_{b}O_{c}, ZrₐSi_{b}O_{c}N_{d}, ZrO₂, other Hf-containing or Zr-containing dielectric material, a doped version of any of the foregoing (lanthanum doped, niobium doped, etc.), or any combination thereof. The gate dielectric layer 92 has a thickness in a range of approximately 5 to approximately 50 nm in a substantially completed electronic device. In alternative embodiment, the transistors 90 may have different gate dielectric layers with different compositions, a different number of films within each gate dielectric layer, significantly different thicknesses, or any combination thereof.

Gate electrodes 94 are formed over the gate dielectric layer 92 using a conventional deposition technique. Each of the gate electrodes 94 can include one or more layers. In one particular embodiment, each gate electrode 94 has a layer closest to the gate dielectric layer 92, wherein such closest layer at least in part establishes the work function of the transistor being formed. In a more particular embodiment when the transistors 90 are p-channel transistors, such closest layer within the gate electrodes 94 can include TiN, MOₐN_{b}, MOₐSi_{b}N_{c}, RuO₂, IrO₂, Ru, Ir, MoSiO, MoSiON, MoHfO, MoHfON, other suitable transition metal containing material, or any combination thereof. In a more particular embodiment when the transistors 90 are n-channel transistors, the gate electrodes 94 can include TaC, TaSiN, TaN, TaSiC, HfC, NbC, TiC, NiSi, other suitable material, or any combination thereof. The gate electrodes 94 can include a heavily doped amorphous silicon or polycrystalline silicon layer, a metal silicide layer, other suitable conductive layer, or a combination thereof that can be used in conjunction with or in place of the closest layers within the gate electrodes 94 as previously described. Each of the gate electrodes 94 has a thickness in a range of approximately 50 to approximately 300 nm.

An optional sidewall oxide layer (not illustrated) can be grown from exposed sides of the gate electrodes 94 to protect the gate electrodes 94 during subsequent processing. The thickness of the optional sidewall oxide layer can be in a range of approximately 2 to approximately 15 nm.

Sidewall spacers 96 and source/drain (“S/D”) regions 98 can be formed. In one embodiment, dopants for extension regions can be implanted after forming the gate electrodes 94 and before forming the sidewall spacers 96. The sidewall spacers 96 can be formed using conventional deposition techniques and may include one or more oxide layers, one or more nitride layers, or a combination thereof. Dopants for heavily doped regions can be implanted after forming the sidewall spacers 96. A thermal cycle can be performed to activate the dopants to form the S/D regions 98, which include extension and heavily doped regions. Portions of the semiconductor layer 22 lying under the gate electrodes and between the S/D regions 98 are channel regions 99. At this point in the process, transistors 90 have been formed.

Although not illustrated in FIG. 9, silicided regions can be formed. More specifically, a metal-containing layer (not illustrated) can be formed over the substrate 12. The metal-containing layer can include a material capable of reacting with silicon to form a silicide, and can include Ti, Ta, Co, W, Mo, Zr, Pt, other suitable material, or any combination thereof. In one embodiment, the metal-containing layer is performed using a conventional deposition technique. Exposed portions of the gate electrodes 94 (if such exposed portions include polysilicon or amorphous silicon), the S/D regions 98 can react with the metal-containing layer to formed silicide regions. Portions of the metal-containing layer that overlie insulating materials (e.g., trench field isolation region 72, sidewall spacers 96, etc.) do not significantly react with each other. Unreacted portions of the metal-containing layer are removed using a conventional technique.

Processing can be continued to form a substantially completed electronic device. One or more insulating layers, one or more conductive layers, and one or more passivating layers are formed using conventional techniques.

The formation of the liner layer 42 before defining the final depth of the trench, in which a trench field isolation region will be subsequently formed, can allow for a better performing electronic device to be formed. The liner layer 42 can help round the corners of the semiconductor layer 22 near the trench field isolation region 72 to improve the integrity of the gate dielectric layer 92 near the edge of the trench field isolation region. Also, by forming the liner layer 42 before etching the trench through the entire thickness of the semiconductor layer 22, undesired bird's beak formation and its undesired associated stresses can be significantly reduced or eliminated.

The concepts described herein can be extended to electronic devices where trench field isolation regions are formed within the substrate 12 (e.g., a substantially monocrystalline semiconductor substrate without the insulating layer 14, i.e., the BOX layer). Regardless of the type of starting material, a trench is etched into a semiconductor material to a first depth before forming the liner layer 42. The trench is further etched into the semiconductor material to a second depth after forming the liner layer 42.

Note that not all of the activities described above in the general description or the examples are required, that a portion of a specific activity may not be required, and that one or more further activities may be performed in addition to those described. Still further, the order in which activities are listed are not necessarily the order in which they are performed. After reading this specification, skilled artisans will be capable of determining what activities can be used for their specific needs or desires.

In the foregoing specification, principles of the invention have been described above in connection with specific embodiments. However, one of ordinary skill in the art appreciates that one or more modifications or one or more other changes can be made to any one or more of the embodiments without departing from the scope of the invention as set forth in the claims below. Accordingly, the specification and figures are to be regarded in an illustrative rather than a restrictive sense and any and all such modifications and other changes are intended to be included within the scope of invention.

Any one or more benefits, one or more other advantages, one or more solutions to one or more problems, or any combination thereof have been described above with regard to one or more specific embodiments. However, the benefit(s), advantage(s), solution(s) to problem(s), or any element(s) that may cause any benefit, advantage, or solution to occur or become more pronounced is not to be construed as a critical, required, or essential feature or element of any or all the claims.

What is claimed is:

1. A process for forming an electronic device comprising:
etching a trench to a first depth in the semiconductor material;
forming a first insulating layer along a sidewall of the trench;
etching the trench to a second depth in the semiconductor material that is deeper than the first trench, wherein etching the trench to the second depth is performed after forming the first insulating layer along the sidewall of the trench;
forming a second insulating layer over the semiconductor material and within the trench to fill the opening; and
removing a portion of the second insulating layer lying outside the trench to define a trench field isolation region.

2. The process of claim 1, further comprising:
forming a pad layer over the semiconductor material; and
forming an oxidation-resistant layer over the pad layer before forming a mask.

3. The process of claim 2, further comprising:
patterning the oxidation-resistant layer to define an opening; and
patterning the pad layer before etching the trench to the first depth, wherein the opening extends through the pad layer after patterning the pad layer.

4. The process of claim 1, wherein the semiconductor material is part of a semiconductor layer that overlies a buried oxide layer that overlies a substrate.

5. The process of claim 1, wherein the semiconductor material is part of a substantially monocrystalline semiconductor substrate.

6. The process of claim 1, wherein forming the first insulating layer along the sidewall of the trench comprises:
forming an oxide film along the sidewall and a bottom of the trench; and
etching the oxide film to expose the bottom of the trench.

7. The process of claim 6, wherein forming the first insulating layer along the sidewall of the trench comprises:
forming a nitride film over the oxide film; and
etching the nitride film to expose a portion of the oxide film lying along the bottom of the trench.

8. The process of claim 1, wherein forming the first insulating layer comprises forming the first insulating layer to a thickness in a range of approximately 1 to approximately 30 nm as measured along the bottom of the trench.

9. The process of claim 1, wherein removing the portions of the second insulating layer is performed using chemical-mechanical polishing.

10. The process of claim 1, wherein removing the portions of the second insulating layer is performed by etching the second insulating layer.

11. The process of claim 1, further comprising forming a transistor, wherein at least a portion of the transistor is formed within the semiconductor material adjacent to the trench field isolation region.

12. The process of claim 11, wherein forming the transistor comprises:
forming a gate dielectric layer from or over the semiconductor material;
forming a gate electrode over the gate dielectric layer; and
forming spaced-apart source/drain regions within the semiconductor material, wherein a channel region lies between the spaced-apart source/drain regions and under the gate electrode.

13. An electronic device comprising:
a semiconductor material that defines a trench including a sidewall and a bottom; and
a trench field isolation region adjacent to the semiconductor material at the sidewall, the trench field isolation region comprising:
a first insulating layer extending from a first point near a top of the sidewall of the trench to a second point that lies at a first depth, wherein the second point is spaced apart from the bottom of the trench; and
a second insulating layer that extends to a third point that lies at a second depth that is closer to the bottom of the trench compared to the second point.

14. The electronic device of claim 13, wherein the semiconductor material is part of a semiconductor layer that overlies a buried oxide layer that overlies a substrate.

15. The electronic device of claim 13, wherein the semiconductor material is part of a substantially monocrystalline semiconductor substrate.

16. The electronic device of claim 13, wherein the first insulating layer comprises an oxide film.

17. The electronic device of claim 16, wherein the first insulating layer further comprises a nitride film, wherein the nitride film lies between the oxide film and the second insulating layer.

18. The electronic device of claim 13, further comprising a transistor, wherein at least a portion of the transistor lies within the semiconductor material and adjacent to the trench field isolation region.

19. The electronic device of claim 13, wherein the second insulating layer fills the trench.

20. A process for forming an electronic device comprising:
forming a first oxide layer over a semiconductor layer that overlies a buried oxide layer that overlies a substrate;
forming a nitride layer over the oxide layer;
forming an opening that extends through the nitride layer and the oxide layer, and a trench extending to a first depth into the semiconductor layer, wherein the trench includes a sidewall and a bottom;
forming a second oxide layer along the sidewall and bottom of the trench;
etching a first portion of the second oxide layer to expose the semiconductor layer lying along the bottom of the trench, wherein a second portion of the second oxide layer lies along a sidewall of the trench after etching the first portion is substantially completed;
etching the semiconductor layer to extend the trench through the semiconductor layer and expose the buried oxide layer;
forming a third oxide layer to fill the trench, wherein:
a first portion of the third oxide layer extends into the trench to a location deeper than the first depth; and
a second portion of the third oxide layer overlies the nitride layer and the first oxide layer;
removing the second portion of the third oxide layer;
removing remaining portions of the nitride layer and the first oxide layer; and
forming an electronic component, wherein at least a portion of the electronic component lies within the semiconductor layer.
